(19) United States
(12) Patent Application Publication
(10) Pub. No.: US 2002/0084919 A1
(43) Pub. Date: Jul. 4, 2002

(54) Configurable keyboard

(76) Inventor: Peter C. Green, Redondo Beach, CA (US)

Correspondence Address: SHARMINI N. GREEN, 2009 A HUNTINGTON LANE, REDONDO BEACH, CA, 90278, US

(21) Appl. No.: 09/999,439

(22) Filed: Nov. 27, 2001

Related U.S. Application Data
(60) Provisional application No. 60/250,282, filed on Nov. 28, 2000.

(51) Int. Cl. H03M 11/00; H03K 17/94

(52) U.S. Cl. 341/22

(57) ABSTRACT

A configurable keyboard comprises a link to a computing device, and a plurality of keys, each of the plurality of keys accepting input from the computing device via the link. The input specifies a function for each of the plurality of keys and each of the plurality of keys displays an image corresponding to the function.

### CROSS-REFERENCE

The present application claims priority to U.S. application Ser. No. 60/250,282, filed on Nov. 28, 2001.

### BACKGROUND OF THE INVENTION

1. Field of Invention

The present invention relates generally to computer keyboards, and more particularly to a configurable keyboard.

2. Description of Prior Art

The conventional computer keyboard provides modem computer software with a board, flexible mechanism for gathering user input. The computer keyboard evolved from a typewriter keyboard, predominantly with the addition of new keys. While the evolution has proved to be significant, there is nonetheless room for improvement.

In particular, many software applications rely on shortcut keys, most of which are combinations of the “Control” or “Alt” keys and some other alphanumeric key. Shortcut keys like “Cntl-X” and “Alt-3” are examples. These key combinations provide users with, a powerful shortcut to performing various tasks. Thus, for example, in Microsoft Word, “Cntl-N” allows a user to create a new document. Unfortunately, there are no standards across applications for these shortcut keys and with the proliferation of software, it is becoming increasingly difficult for users to learn all the shortcuts for various software.

Fortunately, many applications enable the user to perform actions by selecting a toolbar button from a toolbar associated with the application. A toolbar button is a small icon that the user can click on to perform an action. In the Microsoft Word example above, the toolbar button to create a new document is simply an icon for a blank piece of paper. When the user clicks on this icon, a new document is automatically created. The toolbar mechanism is far more user-friendly than shortcut keys. Toolbar icons are highly visual and intuitive for users; it is easier for the user to spot and press a button than to intuit a keyboard combination.

It is therefore desirable to improve keyboards to provide users with a more user friendly and intuitive interface.

### SUMMARY OF THE INVENTION

The present invention discloses a configurable keyboard. More specifically, the present invention discloses a configurable keyboard comprising a link to a computing device, and a plurality of keys, each of the plurality of keys accepting input from the computing device via the link. The input specifies a function for each of the plurality of keys and each of the plurality of keys displays an image corresponding to the function.

### BRIEF DESCRIPTION OF THE DRAWINGS

The present invention is illustrated by way of example and not limitation in the following drawing(s), in which like references indicate similar elements, and in which:

FIG. 1 illustrates an overview of one embodiment of the present invention.

### DETAILED DESCRIPTION OF THE INVENTION

The present invention discloses a configurable keyboard. In the following description for the purposes of explanation, numerous specific details are set forth in order to provide a thorough understanding of the present invention. It will be evident, however, to one skilled in the art, that the present invention may be practiced without these specific details. In other instances, well-known structures and devices are shown in block diagram form for clarity and in order not to obscure the details of the invention.

The present invention may be implemented within any computer system now known or hereafter developed. In one embodiment, such computer systems may comprise a bus for communicating information, a processor coupled with the bus for processing information, main memory coupled with the bus for storing information and instructions for the processor, a read-only memory coupled with the bus for storing static information and instructions for the processor, a display device coupled with the bus for displaying information for a computer user, an input device coupled with the bus for communicating information and command selections to the processor, and a mass storage device, such as a magnetic disk and associated disk drive, coupled with the bus for storing information and instructions. A data storage medium containing digital information may also be configured to operate with the mass storage device to allow the processor to access to the digital information on the data storage medium via the bus.

The computer system may additionally include a network device that enables the computer system to connect to a network, such as the Internet and/or a wireless network. A user may thus use the computer system to communicate on the network via a web browser or other such user interface. The above-described system is not, however, necessary to practice the invention. It is merely illustrative of a present day system within which the invention may be practiced. Alternative embodiments may include any type of computing system that accepts user input.

By combining the features of a shortcut key with toolbar buttons, the present invention discloses a highly configurable keyboard. According to one embodiment of the present invention, such a configurable keyboard may include small LCD displays on each of the keyboard keys. Each application may modify the LCDs to display images customized for the specific application. This enables the application to make shortcut keys available to the user, but in a more intuitive manner. Although the above description assumes the use of LCDs, alternative methods of displaying such images may also be utilized.

According to one embodiment, the present invention includes an Application Programming Interface (API), a driver and the keyboard itself. The API enables applications to send images to the keyboard when they receive keyboard events from the operating system. The API may be provided by the driver or by a compatibility layer in the operating system itself. The driver receives the API calls and translates them into signals that the keyboard can understand. The keyboard interprets the signals and displays the images on the appropriate keys. According to one embodiment of the present invention, the LCDs on keys would typically have a resolution of 32×32 pixels, or 64×32 pixels, depending on the size of the key. Alternate resolutions may also be implemented, especially to take advantage of advances in technology. According to an alternate embodiment, the LCDs would be backlit on the keys to enhance image visibility in poor lighting conditions.

According to yet another embodiment, the configurable keyboard of the present invention may include a “help lock” key and a small multi-character LCD display (called the “help display”) on the keyboard. To use the help lock key, the user would depress it like a caps lock key. Key presses would display help text in the LCD display, indicating the function of the key that was just pressed. Applications may be free to ignore key presses that occurred while the help lock key was down. Alternatively, the keyboard of the present invention may rely on the operating system or the driver to display help on screen for a key that was pressed.

According to one embodiment of the present invention, by default, when the operating systems boots up, it sends images to the configurable keyboard for all of the standard letters and symbols. The keyboard of the present invention would thus appear exactly like a regular keyboard when no keys are pressed. At any time, an application or the operating system itself can modify the images on the keys of the keyboard by making an API call. Applications would commonly respond to “key down” and “key up” messages to determine which keys required their images to be refreshed. According to one embodiment, the API call to change a key's image would look as follows:

void Set_Key_Image(int theKey, void*theImage, char*helpText)

where theKey is a unique index that maps the image to a specific key, theImage is a pointer to image data, and helpText is a pointer to a help string for the help display. For a monochrome 32×32 pixel key, the image data would be 128 bytes in length. It will be obvious to one of ordinary skill in the art that alternate API calls may be utilized without departing from the spirit of the invention.

When the user is using an application, the application may send images to the various keys on the keyboard, to assist the user in identifying which keys perform various functions. Many keys would normally display the expected letters until a “modifier” key such as the CNTRL key, the ALT key, or the SHIFT key was held down by the user. In this situation, the foreground application would send images to all of the keys to which it had mapped keyboard shortcuts. The user would no longer have to remember all sorts of arcane shortcut keys—instead, he or she could just look at the keyboard for the icon signifying the action he required.

In order to avoid multiple applications trying to send images to the keyboard at once, applications may follow a protocol for setting keyboard images. According to one embodiment of the present invention, the operating system reserves some key combinations for itself, and leaves the remainder for the foreground application. According to an alternate embodiment, applications may also reserve certain key combinations.

Thus, for example, if the Windows operating system were to support the configurable keyboard, it may exclusively reserve the right to modify the image of the windows key or the images of other keys when the windows key was depressed. Or, a printing utility might reserve CNTRL-ALT-P to display a queue of print jobs, no matter what application was in the foreground.

The following are other examples:

1. A video game may send a “fire lasers” icon to the space bar. This would visual indicate to the user that the space bar was the “fire lasers” key.

2. The operating system may send the word “help” to the F1 key, to indicate to the user that the F1 key brings up the operating system's help system.

3. Another video game may send the words “HUD off” (short for heads-up-display) to the CAPS LOCK key. This would indicate to the player that as long as the CAPS LOCK key was up, his HUD would be off. If the player then depressed the CAPS LOCK key, the game would show a heads up display on the windshield of the vehicle piloted by the player. The game would then send the words “HUD on” to the CAPS LOCK key to indicate to the player that the HUD was on while the CAPS LOCK key was down.

4. A word processing application may send an image of a scissors to the X key when the CNTRL key is held down. This would signal the user that CNTRL-X means the typical text cut operation.

5. A printing utility may reserve CNTRL-ALT-P to display a queue of print jobs. Whenever the user held down the CNTRL and ALT key, the printing utility would send a “print queue” icon to the P key.

6. A graphics processing application may send images to all of the keys the user could press to manipulate images. It would send a blank image to all of the remaining keys to indicate to the user that they were useless in this particular application.

7. A keyboard utility may replace the QWERTY keyboard layout of the typical keyboard with a Dvorak keyboard layout. This utility would be responsible for remapping the key presses to the correct letters properly before they were sent to the application.

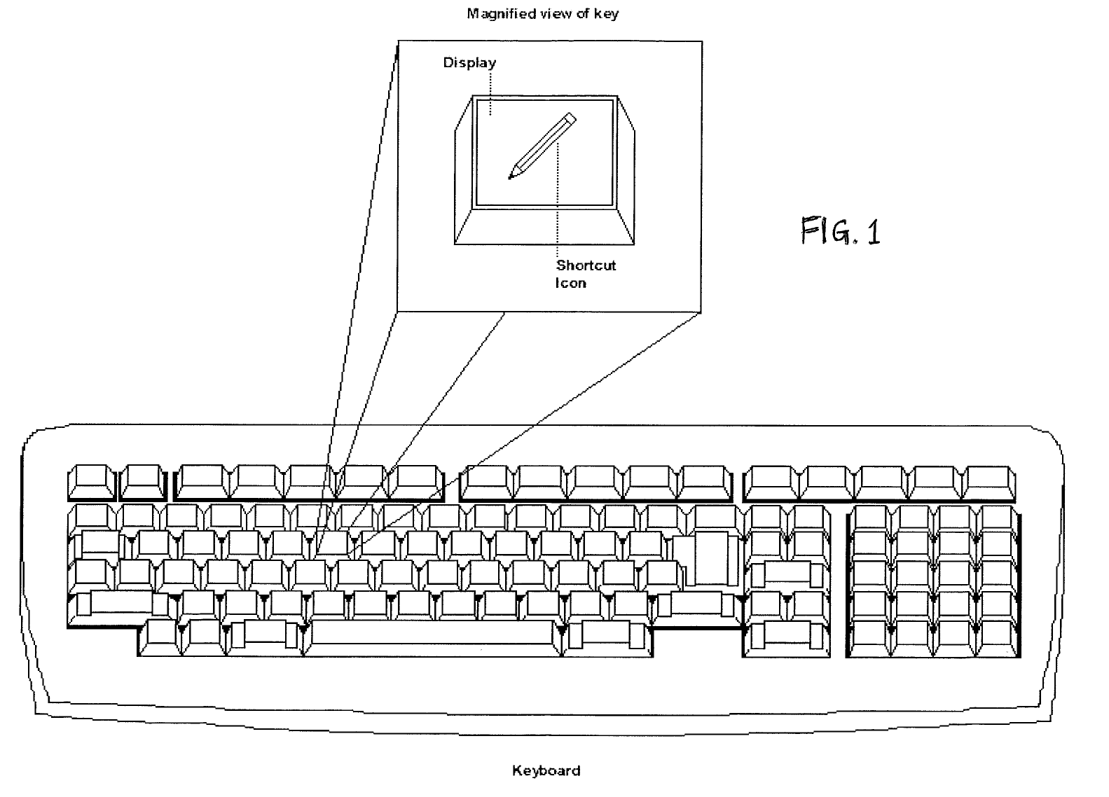

FIG. 1 illustrates an overview of one embodiment of the present invention. A magnified view of a key shows that its display has been updated to show a pencil icon. This simulates functionality that might be found in an interactive keyboard-aware painting application; if the user presses that particular key, he will get access to that application's pencil tool.

Thus, a configurable keyboard is disclosed. Although the present invention has been described with reference to specific exemplary embodiments, it will be evident to those skilled in the art that various changes and modifications may be made to these embodiments, and equivalents may be substituted for elements in these embodiments, without departing from the general spirit and scope of the invention as set forth in the claims. In addition, many modifications may be made to adapt a particular element, technique or implementation to the teachings of the present invention without departing from the central scope of the invention. Accordingly, the specification and drawings should be regarded in an illustrative rather than a restrictive sense.

I claim:

1. A configurable keyboard comprising:
a link to a computing device;
a plurality of keys, each of said plurality of keys accepting input from said computing device via said link, said input specifying a function of each of said plurality of keys, each of said plurality of keys displaying an image corresponding to said function.

2. The configurable keyboard according to claim 1 wherein said input from said computing device is generated by an operating system on said computing device.

3. The configurable keyboard according to claim 1 wherein said input from said computing device is generated by an application on said computing device.

4. The configurable keyboard according to claim 3 wherein said application on said computing device is a video game.

5. The configurable keyboard according to claim 3 wherein said application on said computing device is a word processing application.

6. The configurable keyboard according to claim 3 wherein said application on said computing device is a graphics application.

7. The configurable keyboard according to claim 1 wherein each of said plurality of keys is an LCD.

8. The configurable keyboard according to claim 1 wherein said image is a graphical representation of said function.

9. A method for configuring a keyboard comprising the steps of:
accepting input from a computing device;
translating said input to configure a plurality of keys on said keyboard; and
displaying an image on each of said plurality of keys on said keyboard.
